(19) United States
(12) Patent Application Publication
(10) Pub. No.: US 2019/0252614 A1
(43) Pub. Date: Aug. 15, 2019

(54) MOTHER PLATE, METHOD FOR MANUFACTURING MOTHER PLATE, METHOD FOR MANUFACTURING MASK, AND OLED PIXEL DEPOSITION METHOD

(71) Applicant: TGO TECH. CORPORATION, Gyeonggi-do (KR)

(72) Inventor: Taek Yong JANG, Gyeonggi-do (KR)

(21) Appl. No.: 16/345,884

(22) PCT Filed: Oct. 16, 2017
(86) PCT No.: PCT/KR2017/011362

§ 371 Date: Apr. 29, 2019

(30) Foreign Application Priority Data
Nov. 3, 2016 (KR) 10-2016-0145918
Dec. 1, 2016 (KR) 10-2016-0162464
Apr. 27, 2017 (KR) 10-2017-0054471

(51) Int. Cl. H01L 51/00; H01L 51/56; C25D 1/10; C23C 14/04; C23C 14/24

(52) U.S. Cl. CPC H01L 51/0011; H01L 51/001; C23C 14/24; C25D 1/10; C23C 14/042; H01L 51/56

(57) ABSTRACT

Provided are a mother plate, a method of manufacturing the mother plate, a method of manufacturing a mask, and a method of depositing organic light-emitting diode (OLED) pixels. A method of manufacturing a mother plate 20 used to electroform a mask, according to the present invention, includes (a) providing a substrate 21 made of conductive monocrystalline silicon, and (b) forming an insulator 25 having patterns, on at least one surface of the substrate 21.

### TECHNICAL FIELD

The present invention relates to a mother plate, a method of manufacturing the mother plate, a method of manufacturing a mask, and a method of depositing organic light-emitting diode (OLED) pixels and, more particularly, to a mother plate using monocrystalline silicon in a process of electroforming a plated film, a method of manufacturing the mother plate, a method of manufacturing a mask, and a method of depositing OLED pixels.

### BACKGROUND ART

Currently, research is being conducted on an electroforming method as a thin film manufacturing method. The electroforming method is performed by dipping an anode body and a cathode body in an electrolyte and electrodepositing a metal thin film on the surface of the cathode body by applying electricity, and thus ultra-thin films may be manufactured in a large quantity.

As a pixel deposition technique in an organic light-emitting diode (OLED) manufacturing process, a fine metal mask (FMM) scheme for positioning a thin metal mask (or a shadow mask) in contact with or very close to a substrate and depositing an organic material at desired locations is commonly used.

A general mask manufacturing method includes a method of preparing a metal thin film to be used as a mask, and coating a photoresist (PR) on the metal thin film and then performing pattering, or coating a PR to have patterns and then performing etching to manufacture a patterned mask.

Another general mask manufacturing method includes a method of electroforming a thin film on a metal electrode, and patterning the plated thin film to manufacture a mask.

According to the above-described general FMM mask manufacturing methods, since a PR needs to be coated and etched on a substrate in every process, process time and costs are increased and productivity is reduced.

In an ultra-high-resolution OLED manufacturing process, small defects of several μm may lead to pixel deposition failure and thus defects such as impurities, intervening products, and voids on the surface of an FMM mask need to be minimized. However, when electroforming is performed using a general metal electrode, defects occur on the surface of an electrodeposited film due to micro-scale defects or imperfect or non-uniform crystal structures on the surface of the metal electrode. Therefore, use of a defect-less electrode may be regarded as a first step for manufacturing an FMM mask having uniform thickness and surface state.

### DETAILED DESCRIPTION OF THE INVENTION

### Technical Problem

The present invention provides a mother plate capable of manufacturing a mask having a uniform thickness and an excellent surface state, a method of manufacturing the mother plate, and a method of manufacturing a mask.

The present invention provides a mother plate capable of reducing process time and costs and increasing productivity by repeatedly reusing the mother plate, a method of manufacturing the mother plate, and a method of manufacturing a mask.

### Technical Solution

According to an aspect of the present invention, there is provided a method of manufacturing a mother plate used to electroform a mask for organic light-emitting diode (OLED) pixel deposition, the method including (a) providing a substrate made of conductive monocrystalline silicon, and (b) forming an insulator having patterns, on at least one surface of the substrate.

According to an aspect of the present invention, there is provided a method of manufacturing a mother plate used to electroform a mask for organic light-emitting diode (OLED) pixel deposition, the mother plate including a substrate made of conductive monocrystalline silicon and having engraved patterns formed in at least one surface thereof, and an insulator buried in the engraved patterns.

The substrate may be doped at a concentration equal to or higher than 10¹⁹ cm⁻³.

The insulator may include one of a photoresist, a silicon oxide, and a silicon nitride.

A density of defects having a diameter equal to or greater than 2 μm on the surface of the substrate may be 0 pcs/cm² to 1,156 pcs/cm².

A uniform electric field may be generated and thus a plated film may be formed on a whole exposed part of the surface of the monocrystalline silicon other than a part of the surface where the insulator is formed, formation of the plated film may be prevented on the insulator to pattern the plated film, and the patterned plated film may serve as a fine metal mask (FMM).

According to an aspect of the present invention, there is provided a mother plate used to electroform a mask for organic light-emitting diode (OLED) pixel deposition, the mother plate including a substrate made of conductive monocrystalline silicon, and an insulator formed on at least one surface of the substrate to have patterns.

According to an aspect of the present invention, there is provided a mother plate used to electroform a mask for organic light-emitting diode (OLED) pixel deposition, the mother plate including a substrate made of conductive monocrystalline silicon, and an insulator formed in engraved patterns formed in at least one surface of the substrate.

A density of defects having a diameter equal to or greater than 2 μm on the surface of the substrate may be 0 pcs/cm² to 1,156 pcs/cm².

The substrate may be doped at a concentration equal to or higher than 10¹⁹ cm⁻³.

The insulator may include one of a photoresist, a silicon oxide, and a silicon nitride.

According to an aspect of the present invention, there is provided a method of electroforming a mask for organic light-emitting diode (OLED) pixel deposition, the method including (a) providing a substrate made of conductive monocrystalline silicon, (b) manufacturing a cathode body by forming an insulator having patterns, on at least one surface of the substrate, (c) positioning the cathode body and an anode body spaced apart from the cathode body, and dipping at least a part of the cathode body in a plating solution, and (d) applying an electric field between the cathode body and the anode body.

According to an aspect of the present invention, there is provided a method of electroforming a mask for organic light-emitting diode (OLED) pixel deposition, the method including (a) providing a substrate made of conductive monocrystalline silicon, (b) forming engraved patterns in at least one surface of the substrate, (c) manufacturing a cathode body by forming an insulator in the engraved patterns, (d) positioning the cathode body and an anode body spaced apart from the cathode body, and dipping at least a part of the cathode body in a plating solution, and (e) applying an electric field between the cathode body and the anode body.

A plated film may be formed on the surface of the cathode body to configure a mask body, and formation of the plated film may be prevented on a surface of the insulator to configure mask patterns.

According to an aspect of the present invention, there is provided a method of depositing organic light-emitting diode (OLED) pixels by using a mask electroformed for OLED pixel deposition, the method including (a) positioning a mask electroformed using the above-described method of electroforming the mask, to correspond to a target substrate, (b) supplying an organic material source to the target substrate through the mask, and (c) depositing the organic material source on the target substrate through patterns of the mask.

### Advantageous Effects

As described above, according to the present invention, a mask having a uniform thickness and an excellent surface state may be manufactured.

In addition, according to the present invention, process time and costs may be reduced and productivity may be increased by repeatedly reusing a cathode body mold.

### DESCRIPTION OF THE DRAWINGS

FIG. 1 is a schematic view of an organic light-emitting diode (OLED) pixel deposition apparatus using a fine metal mask (FMM), according to an embodiment of the present invention.

FIG. 2 is a schematic view of an electroforming apparatus according to an embodiment of the present invention.

FIGS. 3A, 3B and 3C are schematic views of a mask according to an embodiment of the present invention.

FIGS. 4A-4D, 5A-5E and 6A-6F are schematic views for describing a process of manufacturing a mother plate, and a process of manufacturing a mask by using the manufactured mother plate, according to embodiments of the present invention.

FIGS. 7A, 7B and 7C illustrate images showing surface defect states of a SUS mother plate, and a surface defect state of an Invar mask manufactured using the SUS mother plate, according to a comparative example.

FIGS. 8A, 8B and 8C illustrate images showing surface defect states of a monocrystalline silicon mother plate of the present invention, and a surface defect state of an Invar mask manufactured using the monocrystalline silicon mother plate, according to a test example.

FIGS. 9A, 9B and 9C illustrate images showing surface defect states of the monocrystalline silicon mother plate of the present invention after performing Secco etching, according to a test example.

### EXPLANATION OF REFERENCE NUMERALS

10: Electroforming apparatus

11: Plating bath

12: Plating solution

15: Plated film

20: Mother plate, Cathode body

21: Conductive substrate

25, 26: Insulator

28: Cathode patterns

30: Anode body

40: Power supply

100: Mask, Shadow mask, Fine Metal Mask (FMM)

200: OLED pixel deposition apparatus

DP: Display patterns

PP: Pixel patterns, Mask patterns

### Mode of the Invention

The following detailed descriptions of the invention will be made with reference to the accompanying drawings illustrating specific embodiments of the invention by way of example. These embodiments will be described in detail such that the invention can be carried out by one of ordinary skill in the art. It should be understood that various embodiments of the invention are different, but are not necessarily mutually exclusive. For example, a specific shape, structure, and characteristic of an embodiment described herein may be implemented in another embodiment without departing from the scope of the invention. In addition, it should be understood that a position or placement of each component in each disclosed embodiment may be changed without departing from the scope of the invention. Accordingly, there is no intent to limit the invention to the following detailed descriptions. The scope of the invention is defined by the appended claims and encompasses all equivalents that fall within the scope of the appended claims. In the drawings, like reference numerals denote like functions, and the dimensions such as lengths, areas, and thicknesses of elements may be exaggerated for clarity.

Hereinafter, to allow one of ordinary skill in the art to easily carry out the invention, embodiments of the present invention will be described in detail with reference to the accompanying drawings.

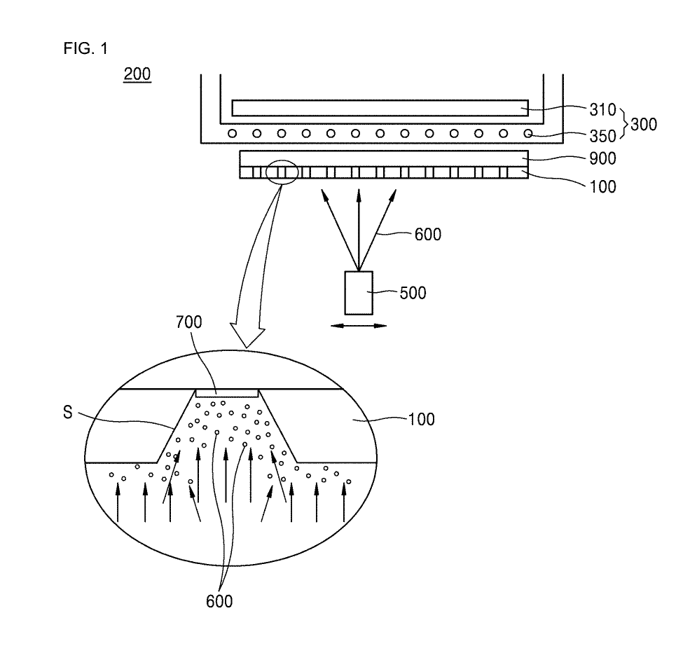

FIG. 1 is a schematic view of an organic light-emitting diode (OLED) pixel deposition apparatus 200 using a fine metal mask (FMM) 100, according to an embodiment of the present invention.

Referring to FIG. 1, the OLED pixel deposition apparatus 200 includes a magnet plate 300 containing a magnet 310 and having a cooling water line 350 installed therein, and a deposition source supply 500 for supplying an organic material source 600 from below the magnet plate 300.

A target substrate 900, on which the organic material source 600 is to be deposited, e.g., a glass substrate, may be provided between the magnet plate 300 and the deposition source supply 500. The FMM mask 100 for enabling deposition of the organic material source 600 per pixel may be positioned in contact with or very close to the target substrate 900. The magnet 310 may generate a magnetic field such that the FMM mask 100 is in contact with or very close to the target substrate 900.

The deposition source supply 500 may supply the organic material source 600 while horizontally reciprocating, and the organic material source 600 supplied from the deposition source supply 500 may pass through patterns of the FMM mask 100 and be deposited on a surface of the target substrate 900. The organic material source 600 deposited through the patterns of the FMM mask 100 may serve as pixels 700 of an OLED.

To prevent non-uniform deposition of each pixel 700 due to a shadow effect, the pattern of the FMM mask 100 may have a sloped shape S [or a tapered shape S]. The organic material source 600 passing through the patterns in diagonal directions along sloped surfaces may also contribute to deposition of the pixels 700 and thus the pixels 700 may be deposited to a uniform thickness.

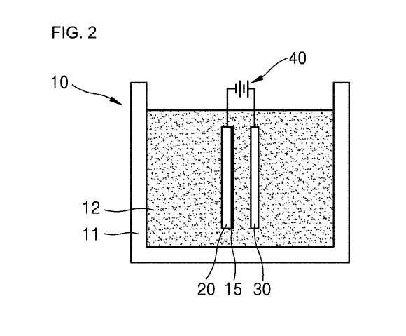

FIG. 2 is a schematic view of an electroforming apparatus 10 according to an embodiment of the present invention. Although a planar electroforming apparatus 10 is illustrated in FIG. 2, the present invention is not limited to the illustration of FIG. 2 and is applicable to known electroforming apparatuses such as a planar electroforming apparatus and a continuous electroforming apparatus.

Referring to FIG. 2, the electroforming apparatus 10 according to an embodiment of the present invention includes a plating bath 11, a cathode body 20, an anode body 30, and a power supply 40. In addition, the electroforming apparatus 10 may further include, for example, a means (not shown) for moving the cathode body 20, a means (not shown) for separating a plated film 15 [or a metal thin film 15] to be used as a mask, from the cathode body 20, and a cutting means (not shown).

The plating bath 11 contains a plating solution 12. The plating solution 12 is an electrolyte and may serve as a material of the plated film 15 to be used as a mask. According to an embodiment, when an Invar thin film made of an iron (Fe)-nickel (Ni) alloy is manufactured as the plated film 15, a mixture of a solution including Ni ions and a solution including Fe ions may be used as the plating solution 12. According to another embodiment, when a Super Invar thin film made of a Fe—Ni—cobalt (Co) alloy is manufactured as the plated film 15, a mixture of a solution including Ni ions, a solution including Fe ions, and a solution including Co ions may be used as the plating solution 12. The Invar thin film or the Super Invar thin film may be used as an FMM mask or a shadow mask in an OLED manufacturing process. Since the Invar thin film has a very low thermal expansion coefficient of about 1.0×10⁻⁶/° C. or the Super Invar thin film also has a very low thermal expansion coefficient of about 1.0×10⁻⁷/° C., mask patterns may not be easily deformed by heat energy and thus the Invar thin film or the Super Invar thin film may be commonly used in a high-resolution OLED manufacturing process. The plating solution 12 for a desired plated film 15 is not particularly limited and the following description will be focused on manufacturing of the Invar thin film 15.

The plating solution 12 may be supplied from an external plating solution supply means (not shown) into the plating bath 11, and the plating bath 11 may further include therein, for example, a circulation pump (not shown) for circulating the plating solution 12, and a filter (not shown) for removing impurities of the plating solution 12.

A side of the cathode body 20 may have, for example, a flat panel shape, and the entirety of the cathode body 20 may be dipped in the plating solution 12. Although the cathode body 20 and the anode body 30 are vertically positioned in FIG. 2, the cathode body 20 and the anode body 30 may be horizontally positioned and, in this case, at least a part or the entirety of the cathode body 20 may be dipped in the plating solution 12.

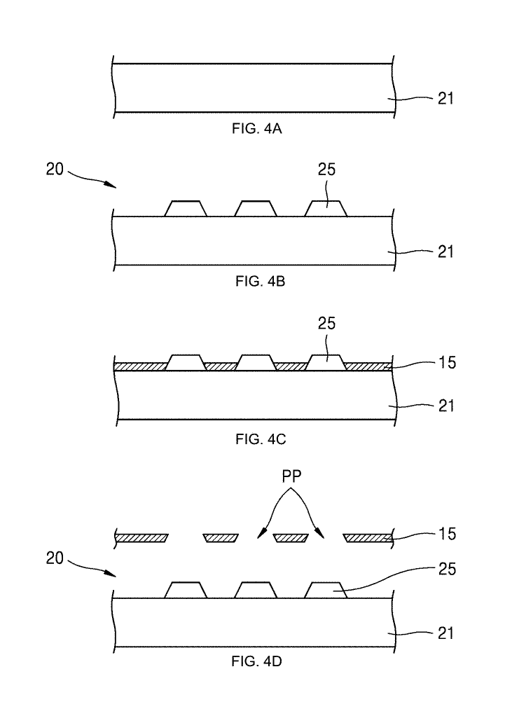

The cathode body 20 may include a conductive material as a substrate 21 [see FIGS. 4 to 6].

A metal substrate may have metal oxides on the surface thereof and include impurities in a metal substrate manufacturing process, a polycrystalline silicon substrate may have an intervening product or a grain boundary, and a conductive polymer substrate may have a high probability of containing impurities and have low strength and acid resistance. In the following description, elements which hinder uniform generation of an electric field on the surface of the cathode body 20, e.g., the metal oxides, the impurities, the intervening product, and the grain boundary, are called “defects”. Due to the defects, an electric field may not be uniformly applied to the above-described cathode material and thus a part of the plated film 15 may be non-uniformly formed.

In implementing ultra-high-resolution pixels of an ultra-high-definition (UHD) or higher level, non-uniformity of the plated film 15 and plated film patterns may exert bad influence on deposition of pixels. An FMM mask or a shadow mask may have a pattern width of several to several ten μm, and more specifically, less than 30 μm and thus even defects of several μm may be significantly regarded considering the pattern width of the mask.

A process for removing, for example, metal oxides and impurities may be additionally performed to remove defects from the above-described cathode material, and other defects, e.g., etching of the cathode material, may be caused in this process.

Therefore, the present invention is characterized in that the conductive substrate 21 of the cathode body 20 uses a substrate made of monocrystalline silicon. To have conductivity, the substrate 21 may be highly doped at a concentration equal to or higher than 10¹⁹ cm⁻³. The doping may be performed on the entirety of the substrate 21 or on only the surface of the substrate 21.

The doped monocrystalline silicon has no defects and thus a uniform plated film 15 may be formed due to generation of a uniform electric field on a whole surface in an electroforming process. The FMM mask 100 manufactured using the uniform plated film 15 may increase the resolution of OLED pixels. Furthermore, since a process for removing or preventing defects is not additionally required, process costs may be reduced and productivity may be increased.

In addition, since the substrate 21 made of silicon is used, when necessary, an insulator 25 or 26 [or an insulating layer] may be formed by merely oxidizing or nitrifying the surface of the substrate 21. The insulator 25 may prevent electrodeposition of the plated film 15 to pattern the plated film 15.

The plated film 15 may be electrodeposited on the surface of the cathode body 20, and be patterned to correspond to the insulator 25 or 26 of the cathode body 20. The cathode body 20 of the present invention may form and pattern the plated film 15 at the same time, and thus may also be called a “mother plate” 20 or a “mold”. Alternatively, the insulator 25 or 26 may not be formed and the plated film 15 may be electrodeposited on the cathode body 20 and then a process of patterning the plated film 15 may be performed additionally.

The anode body 30 may face and be spaced apart from the cathode body 20 by a predetermined distance, a side of the anode body 30 corresponding to the cathode body 20 may have, for example, a flat panel shape, and the entirety of the anode body 30 may be dipped in the plating solution 12. The anode body 30 may be made of an insoluble material such as titanium (Ti), iridium (Ir), or ruthenium (Ru). The cathode body 20 and the anode body 30 may be spaced apart from each other by about several cm.

The power supply 40 may supply a current required for electroplating, to the cathode body 20 and the anode body 30. A negative (−) terminal of the power supply 40 may be connected to the cathode body 20, and a positive (+) terminal thereof may be connected to the anode body 30.

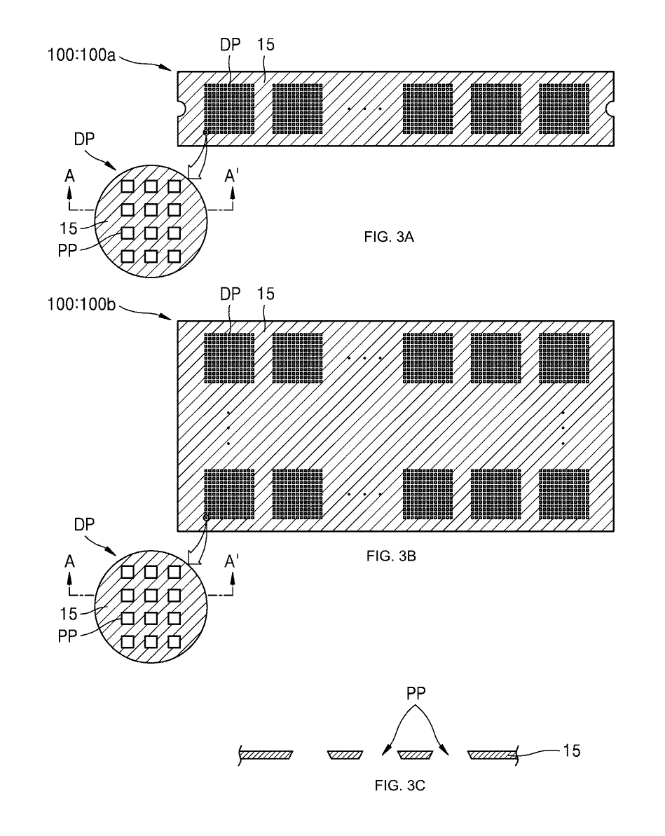

FIG. 3 illustrates schematic views of a mask 100: 100a or 100b according to an embodiment of the present invention.

Referring to FIG. 3, the mask 100: 100a or 100b manufactured using the electroforming apparatus 10 including the mother plate 20 [or the cathode body 20] of the present invention is illustrated. The mask 100a illustrated in (a) of FIG. 3 is a stick-type mask and may be used by welding and fixing both sides of the stick to an OLED pixel deposition frame. The mask 100b illustrated in (b) of FIG. 3 is a plate-type mask and may be used in a process of depositing pixels on a wide area. (C) of FIG. 3 is a vertical cross-sectional view taken along line A-A′ of (a) and (b) of FIG. 3.

A plurality of display patterns DP may be formed in a body of the mask 100: 100a or 100b. Each display pattern DP is a pattern corresponding to a single display of, for example, a smartphone. When the display pattern DP is magnified, a plurality of pixel patterns PP corresponding to red (R), green (G), and blue (B) pixels are shown. Sides of each pixel pattern PP may have a sloped shape or a tapered shape [see FIG. 3C]. An enormous number of pixel patterns PP may be grouped to configure a single display pattern DP, and a plurality of display patterns DP may be formed in the mask 100: 100a or 100b.

That is, in this specification, the display pattern DP does not indicate a single pattern and should be understood as a group of a plurality of pixel patterns PP corresponding to a single display.

The mask 100 of the present invention is characterized in that the mask 100 is manufactured with a plurality of display patterns DP and pixel patterns PP without additionally performing a patterning process. The mask 100 of the present invention is also characterized in that the mask 100 is manufactured with tapered patterns [e.g., pixel patterns PP] without additionally performing a tapering process. In other words, the plated film 15 on the surface of the mother plate 20 [or the cathode body 20] of an electroforming apparatus may be electrodeposited by forming the display patterns DP and the tapered pixel patterns PP. In the following description, the display patterns DP and the pixel patterns PP may be used interchangeably with patterns. Furthermore, although the following description is focused on deposition of the pixel patterns PP in a magnified part of the mother plate 20, since a group of the pixel patterns PP configure the display pattern DP, it should be understood that the pixel patterns PP and the display patterns DP are simultaneously formed in the following embodiments.

FIGS. 4 to 6 illustrate schematic views for describing a process of manufacturing a mother plate 20, and a process of manufacturing a mask 15 or 100 by using the manufactured mother plate 20, according to embodiments of the present invention. FIGS. 4 to 6 show an example of manufacturing the mother plate 20 made of monocrystalline silicon, and the mother plate 20 of the present invention is not limited to the embodiments of FIGS. 4 to 6.

According to a first embodiment, referring to (a) of FIG. 4, a conductive substrate 21 is prepared. The substrate 21 is made of a material used for a cathode body 20, the substrate 21 made of monocrystalline silicon may be used, and highly-doped monocrystalline silicon may be used to have conductivity as described above.

Then, referring to (b) of FIG. 4, an insulator 25 may be formed on at least one surface of the substrate 21. The insulator 25 may be formed with patterns, and more specifically, tapered patterns. The insulator 25 may be made of, for example, a silicon oxide or a silicon nitride using the conductive substrate 21 as a base, or may use a photoresist. When tapered patterns are formed using a photoresist, for example, a multiple exposure scheme or a scheme of varying an exposure intensity per region may be used. As such, a mother plate 20 [or the cathode body 20] may be manufactured.

Subsequently, referring to (c) of FIG. 4, an anode body (not shown) facing the mother plate 20 [or the cathode body 20] is prepare. The anode body (not shown) may be dipped in a plating solution (not shown), and the entirety or a part of the mother plate 20 may be dipped in the plating solution (not shown). A plated film 15 may be electrodeposited on the surface of the mother plate 20 due to an electric field generated between the mother plate 20 [or the cathode body 20] and the facing anode body. However, since the plated film 15 is formed on an exposed part of the surface of the substrate 21 and is not formed on the surface of the insulator 25, patterns PP may be formed in the plated film 15.

Since the plated film 15 is electrodeposited and gets thicker from the surface of the substrate 21, the plated film 15 may not be formed over a top surface of the insulator 25. That is, the thickness of the plated film 15 may be less than the thickness of the insulator 25. Since the plated film 15 is electrodeposited by filling pattern spaces of the insulator 25, the plated film 15 may be formed with an inversely tapered shape to that of the patterns of the insulator 25.

Then, referring to (d) of FIG. 4, the mother plate 20 [or the cathode body 20] is lifted up from the plating solution (not shown). When the plated film 15 is separated from the mother plate 20 outside the plating solution, a part where the plated film 15 is formed may configure the mask 100 [or a mask body] and a part where the plated film 15 is not formed may configure the pixel patterns PP or the display patterns DP [or mask patterns].

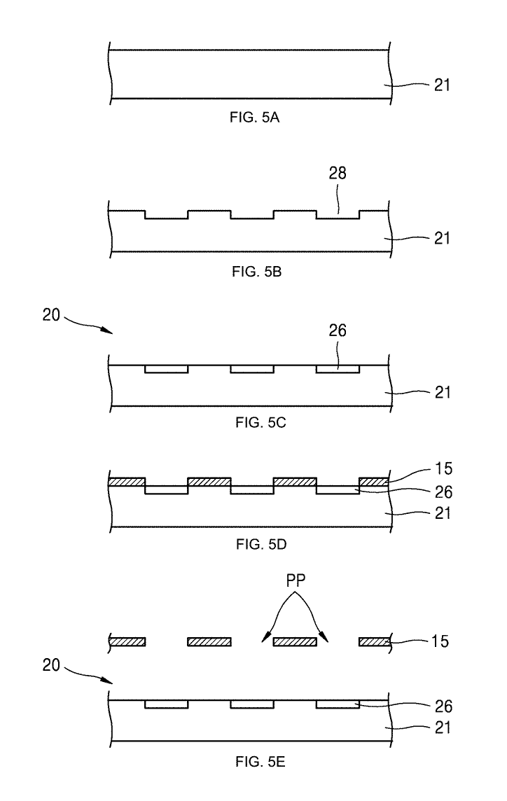

According to a second embodiment, referring to (a) of FIG. 5, a conductive substrate 21 is prepared. This process is the same as that of (a) of FIG. 4 and thus a description thereof will not be provided herein.

Then, referring to (b) of FIG. 5, engraved patterns 28 may be formed in at least one surface of the substrate 21. The engraved patterns 28 may have, for example, a rectangular shape or a tapered shape and be formed using, for example, wet etching or dry etching.

Subsequently, referring to (c) of FIG. 5, an insulator 26 may be buried in the engraved patterns 28. The insulator 26 may be formed in the engraved patterns 28 by using, for example, coating, deposition, or printing. The insulator 26 may be made of, for example, a silicon oxide or a silicon nitride using the conductive substrate 21 as a base, or may use a photoresist. As such, a mother plate 20 [or a cathode body 20] may be manufactured.

Then, referring to (d) of FIG. 5, electroforming is performed. The electroforming process is the same as that of (c) of FIG. 4 and thus a description thereof will not be provided herein. A plated film 15 may be electrodeposited on the surface of the substrate 21 other than a part where the engraved patterns 28 [or the insulator 26] are positioned. Since the plated film 15 is not formed on the surface of the insulator 26, patterns PP may be formed in the plated film 15.

Subsequently, referring to (e) of FIG. 5, the plated film 15 is separated from the mother plate 20 [or the cathode body 20]. This process is the same as that of (d) of FIG. 4 and thus a description thereof will not be provided herein.

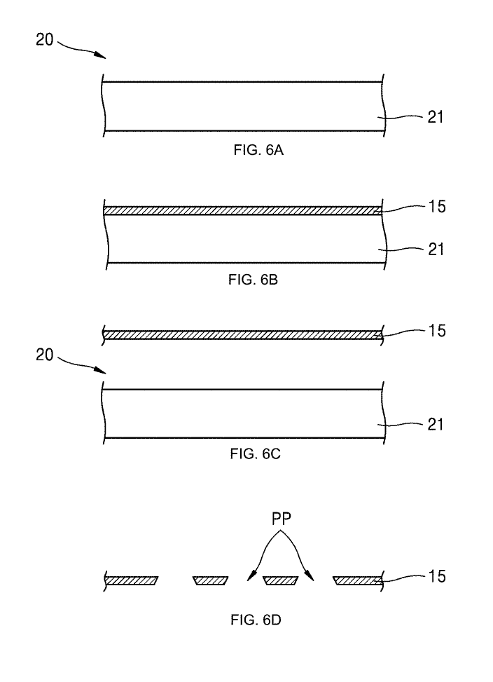

According to a third embodiment, referring to (a) of FIG. 6, a conductive substrate 21 is prepared. This process is the same as that of (a) of FIG. 4 and thus a description thereof will not be provided herein.

Then, referring to (b) of FIG. 6, electroforming is performed by using the conductive substrate 21 itself as a mother plate 20. A plated film 15 may be formed on a whole surface of the conductive substrate 21. The electroforming process is the same as that of (c) of FIG. 4 and thus a description thereof will not be provided herein.

Subsequently, referring to (c) of FIG. 6, the plated film 15 is separated from the mother plate 20 [or a cathode body 20]. This process is the same as that of (d) of FIG. 4 and thus a description thereof will not be provided herein. However, mask patterns are not formed in the plated film 15.

Thereafter, referring to (d) of FIG. 6, mask patterns PP may be formed in the plated film 15. The mask patterns PP may use, for example, lithography, etching, or laser etching using a photoresist. The mask patterns PP may have, for example, a rectangular shape or a tapered shape.

As described above, the mother plate 20 [or the cathode body 20] including the conductive monocrystalline silicon substrate 21 according to embodiments of the present invention may have no or very few defects on the surface thereof. In particular, defects having a diameter equal to or greater than 2 μm, which may influence mask patterns having a width of several to several ten μm, may not be present. Since the mother plate 20 including the conductive monocrystalline silicon substrate 21 may have a much lower density of defects compared to that of a mother plate [or a cathode body] including a metal or polycrystalline silicon substrate, an electric field may be uniformly applied to the surface of the mother plate 20 and thus the plated film 15 electrodeposited on the mother plate 20 may also have a low density of defects on the surface thereof. Therefore, the plated film 15 may have a uniform thickness and an excellent surface state and stably perform pixel deposition by using accurate mask patterns.

A SUS mother plate will now be compared to a monocrystalline silicon mother plate based on a test.

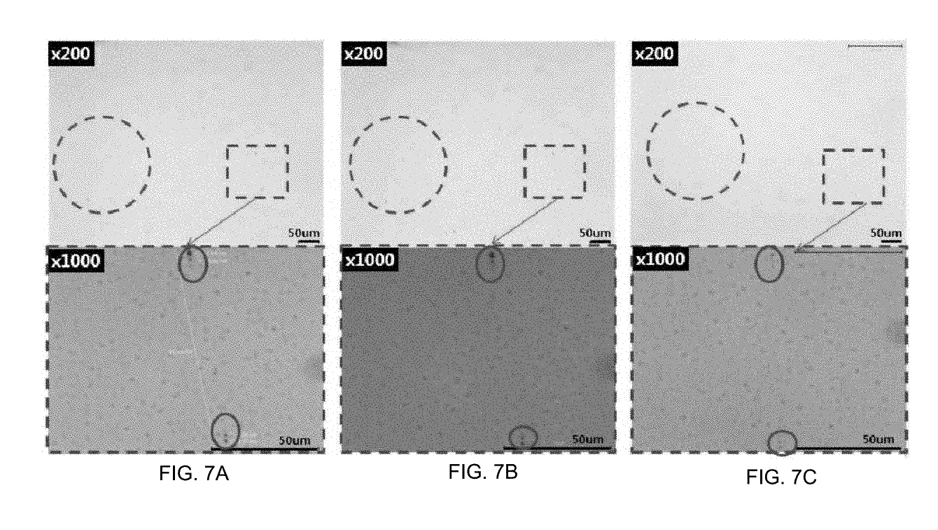

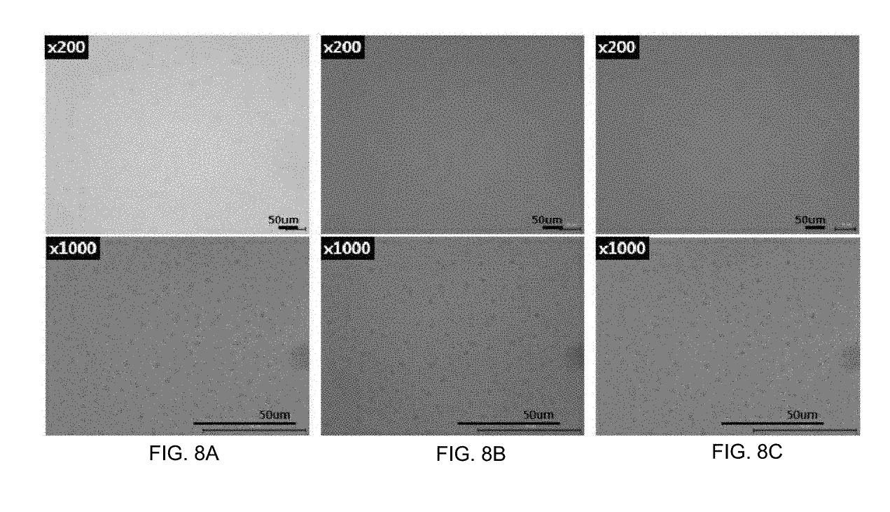

FIG. 7 illustrates images showing surface defect states of a SUS mother plate, and a surface defect state of an Invar mask manufactured using the SUS mother plate, according to a comparative example. FIG. 8 illustrates images showing surface defect states of a monocrystalline silicon mother plate 20 of the present invention, and a surface defect state of an Invar mask 15 or 100 manufactured using the monocrystalline silicon mother plate 20, according to a test example.

The monocrystalline silicon mother plate 20 was prepared, and the SUS mother plate was prepared as a comparative example for the monocrystalline silicon mother plate 20. A mixture of a solution including Ni ions and a solution including Fe ions was used as a plating solution 12, and electroforming was performed at a current density of 60 mA/cm² for 10 minutes. The plated film 15 [or the mask 100] was formed to a thickness of 10 μm.

Defects such as impurities, intervening products, and metal oxides having a diameter equal to or greater than 2 μm were counted. Considering that a width of mask patterns PP may be reduced to 10 μm, 2 μm corresponds to 20% of the mask pattern width and thus defects having a diameter equal to or greater than 2 μm are regarded as a major factor which causes pixel deposition failure. The number of defects within a predetermined area (e.g., 600 μm×500 μm, 0.003 cm²) were counted at a magnification of ×200, and then were multiplied by converting the predetermined area into a unit area of 1 cm².

(a) of FIG. 7 shows a surface state of the SUS mother plate before plating, (b) of FIG. 7 shows a surface state of the SUS mother plate after plating, and (c) of FIG. 7 shows a surface state of the Invar mask electroformed using the SUS mother plate. To specify locations of defects before and after plating at a magnification of ×200, a few noticeable defects are used as references (see blue dashed circles and red dashed rectangles).

A density of defects (the number of defects/cm²) is 38,362 pcs/cm² in (a) of FIG. 7, is 27,463 pcs/cm² in (b) of FIG. 7, and is 12,396 pcs/cm² in (c) of FIG. 7. The density of defects is reduced after the SUS mother plate is plated but it is regarded that the reduction is achieved due to, for example, removal of defects in the electroforming process, detachment of defects to the plating solution, and transfer of defects to the plated Invar film.

In particular, a density of defects of 12,396 pcs/cm² is observed on the electroformed Invar mask [see (c) of FIG. 7]. It is shown that locations of defects on the Invar mask well match locations of defects on the SUS mother plate. This means that an electric field is non-uniformly generated at the locations of the defects on the SUS mother plate, and thus the surface of the plated film is non-uniformly formed. A ratio of transferring the defects of the mother plate to the plated film may be determined to be about (12,396/38,362)×100=32.3(%).

(a) of FIG. 8 shows a surface state of the monocrystalline silicon mother plate 20 before plating, (b) of FIG. 8 shows a surface state of the monocrystalline silicon mother plate 20 after plating, and (c) of FIG. 8 shows a surface state of the Invar mask 15 or 100 electroformed using the monocrystalline silicon mother plate 20.

A density of defects (the number of defects/cm²) is 0 pcs/cm² in all of (a), (b), and (c) of FIG. 8. That is, this means that the monocrystalline silicon mother plate 20 of the present invention has, on the surface thereof, no defects such as oxides, impurities, and intervening products having a diameter equal to or greater than 2 μm.

In particular, the density of defects of 0 pcs/cm² is also observed on the electroformed Invar mask [see (c) of FIG. 8]. Since the mother plate 20 has no defects having a diameter equal to or greater than 2 μm, it is shown that an electric field is uniformly generated on a whole surface of the mother plate 20 and thus the surface of the plated film 15 or 100 is uniformly formed.

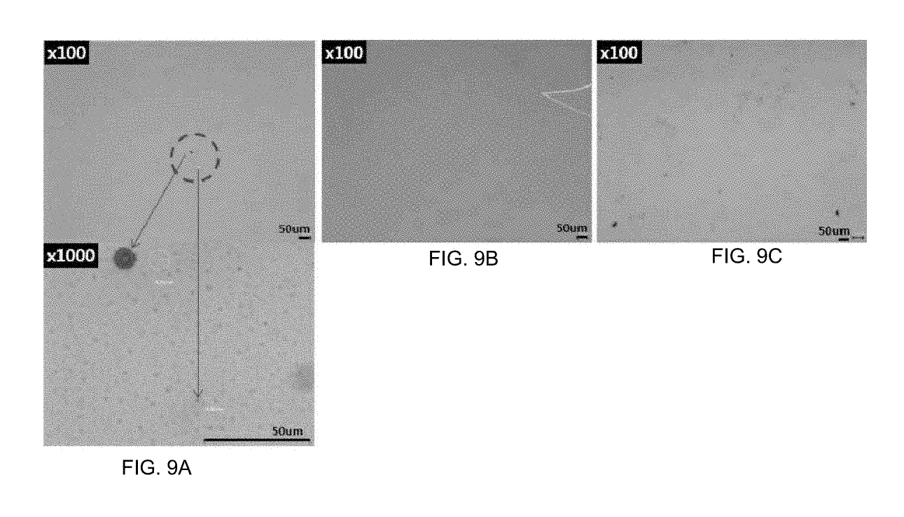

FIG. 9 illustrates images showing surface defect states of the monocrystalline silicon mother plate 20 of the present invention after performing Secco etching, according to a test example.

The density of defects of the monocrystalline silicon mother plate 20 is 0 pcs/cm² in FIG. 8. To check an upper limit, other than a lower limit, of the density of defects, defects of the monocrystalline silicon mother plate 20 was amplified as much as possible and the density of defects was measured in FIG. 9.

As a process for removing surface oxides of the monocrystalline silicon mother plate 20, etching was performed for 15 minutes by using a hydrogen fluoride (HF) (49%) solution. Thereafter, Secco etching was performed for 2 minutes by using a Secco etchant of HF:DI water:K₂Cr₂O₇=1.5L:0.75L:33 g. Secco etching is an etching process for checking defects of silicon. Since parts having defects are etched at a high etching rate, defects of the monocrystalline silicon mother plate 20 may be amplified as much as possible.

(a), (b), and (c) of FIG. 9 are images showing defects at different locations on the mother plate 20 after Secco etching. 2, 9, and 32 defects having a diameter equal to or greater than 2 μm are shown in (a), (b), and (c) of FIG. 9, respectively. An area of measuring defects is 1.24×10⁻² cm². When this area is converted into a unit area, a density of defects (the number of defects/cm²) is 161 pcs/cm² in (a) of FIG. 9, is 726 pcs/cm² in (b) of FIG. 9, and is 2,581 pcs/cm² in (c) of FIG. 9, and an average value thereof is 1,156 pcs/cm².

Therefore, the density of defects (i.e., 1,156 pcs/cm²) on the monocrystalline silicon mother plate 20 of FIG. 9 corresponds to merely 3% of the density of defects (i.e., 38,362 pcs/cm²) on the SUS mother plate of FIG. 7. Even when an Invar mask is electroformed using the monocrystalline silicon mother plate 20 of FIG. 9, the defects of which are amplified, it may be expected that the density of defects will be less than 1,156 pcs/cm² [when the defect transfer ratio of FIG. 7 (i.e., 32.3(%)) is equally applied, 1,156×0.323=373 pcs/cm² is calculated].

Considering FIGS. 8 and 9, when the Invar mask 15 or 100 is electroformed using the monocrystalline silicon mother plate 20 of the present invention, it may be regarded that the density of defects having a diameter equal to or greater than 2 μm ranges from 0 pcs/cm² to less than 1,156 pcs/cm². Therefore, compared to a plated film that is electrodeposited by using, for example, metal or polycrystalline silicon as an electrode body, a plated film that is electrodeposited by using, for example, monocrystalline silicon of the present invention as an electrode body may have a remarkably low density of defects.

As described above, due to a very low density of surface defects, the monocrystalline silicon mother plate 20 of the present invention may generate a uniform electric field in an electroforming process and manufacture the plated film 15 [or the mask 100] having a uniform thickness and an excellent surface state. In addition, the plated film 15 [or the mask 100] may have accurate mask patterns having no μm-scale errors and thus ultra-high-resolution OLED pixels may be deposited.

While the present invention has been particularly shown and described with reference to embodiments thereof, it will be understood by one of ordinary skill in the art that various changes in form and details may be made therein without departing from the scope of the present invention as defined by the following claims.

1. A method of manufacturing a mother plate used to electroform a mask for organic light-emitting diode (OLED) pixel deposition, the method comprising:
(a) providing a substrate made of conductive monocrystalline silicon; and
(b) forming an insulator having patterns, on at least one surface of the substrate.

2. (canceled)

3. The method of claim 1, wherein the substrate is doped at a concentration equal to or higher than 10¹⁹ cm⁻³.)

4. The method of claim 1, wherein the insulator comprises one of a photoresist, a silicon oxide, and a silicon nitride.)

5. The method of claim 1, wherein a density of defects having a diameter equal to or greater than 2 μm on the surface of the substrate is 0 pcs/cm² to 1,156 pcs/cm².)

6. The method of claim 1, wherein a uniform electric field is generated and thus a plated film is formed on a whole exposed part of the surface of the monocrystalline silicon other than a part of the surface where the insulator is formed, formation of the plated film is prevented on the insulator to pattern the plated film, and the patterned plated film serves as a fine metal mask (FMM).

7. A mother plate used to electroform a mask for organic light-emitting diode (OLED) pixel deposition, the mother plate comprising:
a substrate made of conductive monocrystalline silicon; and
an insulator formed on at least one surface of the substrate to have patterns.

8. (canceled)

9. The mother plate of claim 7, wherein a density of defects having a diameter equal to or greater than 2 μm on the surface of the substrate is 0 pcs/cm² to 1,156 pcs/cm².)

10. The mother plate of claim 7, wherein the substrate is doped at a concentration equal to or higher than 10¹⁹ cm⁻³.)

11. The mother plate of claim 7, wherein the insulator comprises one of a photoresist, a silicon oxide, and a silicon nitride.

12. A method of electroforming a mask for organic light-emitting diode (OLED) pixel deposition, the method comprising:
(a) providing a substrate made of conductive monocrystalline silicon;
(b) manufacturing a cathode body by forming an insulator having patterns, on at least one surface of the substrate;
(c) positioning the cathode body and an anode body spaced apart from the cathode body, and dipping at least a part of the cathode body in a plating solution; and
(d) applying an electric field between the cathode body and the anode body.

13. (canceled)

14. The method of claim 12, wherein a plated film is formed on the surface of the cathode body to configure a mask body, and formation of the plated film is prevented on a surface of the insulator to configure mask patterns.

15. (canceled)

16. The method of claim 1, wherein the mother plate is used as a cathode body in electroforming.

17. The method of claim 7, wherein the mother plate is used as a cathode body in electroforming.

18. The method of claim 12, wherein the mask is made of Invar or Super Invar.

19. The method of claim 14, wherein the width of the mask patterns is at least less than 30 μm.

20. The method of claim 12, wherein a density of defects having a diameter equal to or greater than 2 μm on the surface of the substrate is 0 pcs/cm² to 1,156 pcs/cm², and
wherein a density of defects having a diameter equal to or greater than 2 μm on the surface of the mask is less than 1,156 pcs/cm².
